(19) United States
(12) Patent Application Publication
(10) Pub. No.: US 2024/0140863 A1
(43) Pub. Date: May 2, 2024

(54) Glass Cloth and Method of Manufacture

(71) Applicant: Shin-Etsu Chemical Co., Ltd., Tokyo (JP)

(72) Inventors: Hajime ITOKAWA, Annaka-shi (JP); Yusuke TAGUCHI, Annaka-shi (JP); Ryunosuke NOMURA, Annaka-shi (JP); Kazuaki URANAKA, Annaka-shi (JP)

(73) Assignee: Shin-Etsu Chemical Co., Ltd., Tokyo (JP)

(21) Appl. No.: 18/497,527

(22) Filed: Oct. 30, 2023

(30) Foreign Application Priority Data
Oct. 31, 2022 (JP) 2022-174385

(51) Int. Cl. C03C 25/68; B32B 5/02; C03C 3/06; C03C 3/091; C03C 13/00; C08J 5/24; H05K 1/03

(52) U.S. Cl. CPC C03C 25/68; B32B 5/024; C03C 3/06; C03C 3/091; C03C 13/00; C08J 5/248; H05K 1/0366; B32B 2260/021; B32B 2260/046; B32B 2262/101; B32B 2457/08; C03C 2201/02; C03C 2203/52; H05K 2201/029

(57) ABSTRACT

In a glass cloth made of glass filaments having a composition which is at least 50 wt % SiO₂, the filaments have a diameter that is 0.5 μm or more and less than 3.0 μm. The glass cloth has a thickness of 15 μm or less and a weight of from 0.3 to 10 g/m².

### CROSS-REFERENCE TO RELATED APPLICATIONS

This non-provisional application claims priority under 35 U.S.C. § 119(a) on Patent Application No. 2022-174385 filed in Japan on Oct. 31, 2022, the entire contents of which are hereby incorporated by reference.

### TECHNICAL FIELD

The present invention relates to a glass cloth having an excellent dielectric loss tangent and strength, and to a method of manufacturing such a glass cloth. The invention additionally relates to a prepreg, to a laminate and to a printed wiring board.

### BACKGROUND ART

With the trend today toward higher performance and faster communications in information devices such as smartphones, remarkable advances are being made toward achieving, in the printed wiring boards used in such devices, higher densities and ultrathin dimensions, and also lower permittivity and dielectric loss tangent. Laminates produced by stacking prepregs obtained by impregnating a glass cloth with an epoxy resin or other thermosetting resin (referred to below as the “matrix resin”) and curing under applied heat and pressure are widely used as the insulation material in such printed wiring boards.

To achieve ultrathin dimensions in a printed wiring board, the glass cloth itself must be made ultrathin. The glass cloth is produced by collecting a plurality of filaments into a strand, applying twist to the strand so as to form a yarn, then weaving such yarns into a cloth. The thickness of the glass cloth can be lowered by making the diameter of the individual filaments (referred to below as simply the “filament diameter”) smaller. In JP-A 2005-54293, a glass cloth having a filament diameter of 4 μm is obtained, but glass cloth having an even smaller filament diameter will be needed to satisfy the future demand for thinner glass cloth. However, glass filament with a diameter of less than 3 μm has a very low strength because the fibers are so slender, and so the filaments often break and form fuzz when they are collected into strands or when the strands are twisted into yarn, making it impossible to obtain a glass cloth of sufficient strength.

Also, to prevent fuzz and filament breakage from occurring in glass cloth due to mechanical abrasion during winding and weaving, the strands of glass fiber are coated with size during spinning or warping. Prior to silane treatment, the size is completely removed by thermal decomposition, or “heat-cleaning,” treatment. Generally, when a glass cloth is heated, it thermally expands and the filaments rub against each other, giving rise to microcracks and a loss of strength. The deterioration in strength is especially acute for quartz glass—which has an excellent dielectric loss tangent—because it is hard and brittle. When a thin glass cloth is heat cleaned in particular, the strength dramatically decreases; even if silane treatment is applied to the glass cloth, the strength of the cloth remains extremely low and it ends up tearing in the resin coating operation.

There is a desire for printed wiring boards which, in addition to being made thinner, have been conferred with a lower permittivity and a lower dielectric loss tangent. A low dielectric loss tangent is desired in the glass cloth, and glass cloths of improved dielectric properties, including those made of D-glass, NE-glass, L-glass or quartz glass, have been described. Glass cloth contains SiO₂ as the main component. When heated to an elevated temperature of 200° C. or above, the glass cloth takes up moisture from the air, leading to the cleavage of Si—O—Si bonds and the formation of SiOH groups, as a result of which the dielectric loss tangent tends to worsen. For this reason, when heat cleaning is carried out, a glass cloth having a dielectric loss tangent which is worse than what one expect from the dielectric loss tangent of the glass starting materials ends up being obtained. This tendency is especially striking for quartz glass cloth having a high SiO₂ concentration.

In light of the above, there exists a desire for glass cloth of excellent dielectric properties and strength which has a filament diameter of less than 3 μm. However, because glass filament having a diameter of less than 3 μm is exceedingly fine, using such filament to weave a glass cloth of good strength has been difficult.

Additional related art is described in JP-A H05-170483, JP-A 2009-263569, JP-A 2009-19150, JP-A 2006-282401 and JP-A 2005-54293.

### SUMMARY OF THE INVENTION

It is therefore an object of the present invention to provide a glass cloth which has a filament diameter of 0.5 μm or more and less than 3.0 μm, a thickness of 15 μm or less and a weight of from 0.3 to 10 g/m², and which moreover possesses an excellent dielectric loss tangent and an excellent tensile strength. A further object is to provide a method of manufacturing such a glass cloth.

We have conducted intensive investigations aimed at achieving the above objects, as a result of which we have discovered that by weaving a glass cloth from glass filaments and subsequently etching the glass cloth to reduce the filament diameter, a glass cloth having a filament diameter of less than 3 μm and a thickness of 15 μm or less can be obtained while avoiding problems during weaving. In addition, we have found that it is possible to simultaneously remove size when etching the glass cloth. With this method, the size can be removed while suppressing Si—O—Si bond cleavage during heating and thus maintaining the strength of the cloth, enabling a glass cloth of low dielectric tangent loss and high strength to be obtained.

Accordingly, in a first aspect, the invention provides a glass cloth made of glass having a composition that is at least 50 wt % SiO₂, wherein the glass cloth has a filament diameter of 0.5 μm or more and less than 3.0 μm, a thickness of 15 μm or less and a weight of from 0.3 to 10 g/m².

In a preferred embodiment of the glass cloth of the invention, the composition includes a combined amount of SiO₂ and B₂O₃ that is 65 wt % or more.

In another preferred embodiment of the inventive glass cloth, the composition is at least 95 wt % SiO₂.

In a second aspect, the invention provides a method of manufacturing glass cloth, which method includes the step of etching the glass cloth with one or more etching solution selected from the group consisting of hydrofluoric acid, aqueous ammonium fluoride, aqueous sodium hydroxide, aqueous potassium hydroxide, aqueous sodium carbonate, ammonia water and alkaline electrolyzed water.

In a third aspect, the invention provides a method of adjusting the filament diameter of a glass cloth, which method includes the step of etching away at least 0.5 μm of the filament diameter by treating the glass cloth with one or more etching solution selected from the group consisting of hydrofluoric acid, aqueous ammonium fluoride, aqueous sodium hydroxide, aqueous potassium hydroxide, aqueous sodium carbonate, ammonia water and alkaline electrolyzed water.

In a preferred embodiment of the filament diameter adjusting method according to the third aspect of the invention, the etching solution is alkaline electrolyzed water having a pH of 12 or more.

In another preferred embodiment of the filament diameter adjusting method of the invention, glass cloth having a filament diameter of 3.0 μm or more is etched with an etching solution to adjust the filament diameter to 0.5 μm or more and less than 3.0 μm.

In a fourth aspect, the invention provides a desizing method which includes the step of etching glass cloth which has a filament diameter of 3.0 μm or more and in which size adheres to filament surfaces so as to remove the size.

In a fifth aspect, the invention provides a prepreg which includes the glass cloth according to the first aspect of the invention and an organic resin.

In a sixth aspect, the invention provides a laminate which includes the glass cloth according to the first aspect of the invention and an organic resin.

In a seventh aspect, the invention provides a printed wiring board which includes the glass cloth according to the first aspect of the invention and an organic resin.

### Advantageous Effects of the Invention

The invention makes it possible to provide glass cloth which, in spite of having a filament diameter of 0.5 μm or more and less than 3.0 μm, a thickness of 15 μm or less and a weight of from 0.3 to 10 g/m², possesses an excellent dielectric loss tangent and an excellent tensile strength. This glass cloth has outstanding effects in that it makes it possible to adapt to the multilayering of printed wiring boards used in 5G and other high-speed communication technologies which will see increasing use in the future and it can hold down transmission loss.

### DETAILED DESCRIPTION OF THE INVENTION

The objects, features and advantages of the invention will become more apparent from the following detailed description.

Glass Ingredients

The glass used in the glass cloth of the invention has a composition which is at least 50 wt % SiO₂. At a SiO₂ content below 50 wt %, in the subsequently described etching step, other metallic ingredients become major ingredients of the glass cloth and melting proceeds non-uniformly, as a result of which the strength markedly decreases. From the standpoint of electrical characteristics such as the dielectric loss tangent and physical characteristics such as the coefficient of thermal expansion, the SiO₂ content of the silica glass cloth is preferably 95 wt % or more, and more preferably 98 wt % or more. Examples of other metallic ingredients include B₂O₃, Al₂O₃, MgO, CaO, ZnO, Fe₂O₃, Li₂O, TiO₂, Na₂O, SrO, Cr₂O₃, As₂O₃, Sb₂O₃, P₂O₅, ZrO₂, Cl₂, SO₃ and MoO₂. These may be included in any proportions within ranges where the glass cloth of the invention can be produced. Increasing the content of SiO₂ and B₂O₃ enhances the dielectric properties, and so the combined content of SiO₂ and B₂O₃ is preferably 65 wt % or more, and more preferably 70 wt % or more. The content of SiO₂ is even more preferably 95 wt % or more.

Glass Cloth

The glass cloth has a filament diameter which is 0.5 μm or more and less than 3.0 μm, preferably from 0.5 to 2.9 μm, more preferably from 1 to 2.5 μm, and even more preferably 1.0 μm or more and less than 2.5 μm. At less than 0.5 μm, it is difficult to maintain a fiber shape. The filament diameter is the average value of measurements taken under a microscope at ten places on a filament. Details are provided below in the “Examples” section of this Specification.

The glass cloth has a thickness of 15 μm or less, and preferably 10 μm or less. There is no particular lower limit, although a minimum thickness of 0.5 μm or more may be suitably selected. The thickness of the glass cloth is measured according to the method for measuring the thickness of cloths and mats described in JIS R 3420.

The glass cloth has a weight of from 0.3 to 10 g/m², and preferably from 0.5 to 8.0 g/m². At a weight of less than 0.3 g/m², the glass cloth is very difficult to handle. At a filament diameter of 3.0 μm or more, a thickness of more than 15 μm and a weight greater than 10 g/m², the glass cloth will be unable to adapt to future printed wiring board requirements. The weight of the glass cloth is measured according to the method for measuring the thickness of cloths and mats described in JIS R 3420.

The glass cloth following silane treatment in this invention has a dielectric loss tangent at 10 GHz which is preferably less than 0.0070, more preferably 0.0020 or less, even more preferably 0.0010 or less, and still more preferably 0.0008 or less. The dielectric loss tangent at 40 GHz is preferably 0.0100 or less, more preferably 0.0085 or less, even more preferably 0.0030 or less, still more preferably 0.0025 or less, and most preferably 0.0010 or less. There is no particular lower limit, although a minimum dielectric loss tangent of 0.00010 or more may be suitably selected. Measurement of the dielectric loss tangent is based on the resonance method. This is described in detail in the subsequent “Examples” section. In addition, the surface of the glass cloth may have a silane coupling agent adhering thereto. This is explained in the description of the method of manufacturing the glass cloth.

Strength of Glass Cloth

The glass cloth of the invention has a tensile strength which is preferably 0.05 GPa or more, more preferably 0.10 GPa or more, even more preferably 0.15 GPa or more, and still more preferably 0.20 GPa or more. At a tensile strength below 0.05 GPa, the cloth may rupture in subsequent steps, such as during resin coating. A higher tensile strength is better, although it is generally suitable to select the tensile strength from values up to about 10 GPa. The tensile strength of the glass cloth is measured in accordance with the method for measuring tensile strength described in JIS R 3420. The results are shown below.

Tensile strength (GPa)=(tensile strength (N/25 mm)×specific gravity (2.2 g/cm³))/(25×weight (g/m²))

Method of Manufacturing Glass Cloth

The method of manufacturing the glass cloth of the invention is not particularly limited. For example, the method may be one which includes a glass cloth etching step.

Glass Cloth Prior to Etching

The method of producing the initial glass cloth prior to etching, although not particularly limited, is preferably one which produces glass filaments, collects the filaments into strands, applies twist to the strands so as to produce yarn, and then weaves the yarn into glass cloth on a loom.

Glass filament producing methods include, without particular limitation, the method of drawing filaments under heating from an ingot of a prescribed glass formulation, and the method of melting starting materials to form molten glass and then using a bushing to extrude the glass as filaments. At a SiO₂ content of 95 wt % or more, the high melting temperature of the glass makes drawing the glass into filaments with a bushing difficult, and so hot drawing with the use of an oxyhydrogen burner is preferred.

A binder is applied to the surfaces of the drawn glass filaments and the filaments are collected together to a form glass strand. The binder is composed chiefly of starch; a softener or lubricant may be included to impart functionality. The binder composition is commonly referred to as “size” and the process of applying size to glass filaments is known as “sizing.” A known method may be used for sizing. The type of size and the sizing method are not particularly limited, a method which does not readily give rise to fuzz or filament breakage being suitably selected. Fuzz and filament breakage are alleviated by sizing. Sizing methods include dipping, application with a roller or belt-type applicator, and spraying. Twist is applied to the resulting glass strand, giving a glass yarn. The amount of twist is preferably from 0.1 to 5.0 turns per 25 mm.

Glass cloth can be manufactured by weaving quartz glass yarn. When producing the glass cloth of the invention, the weight prior to etching is preferably from 5 to 50 g/m². To reduce the amount of subsequent etching, the weight prior to etching is more preferably from 5 to 25 g/m². Weaving methods include, without particular limitation, methods that involve the use of, for example, an air jet loom, water jet loom, rapier loom or shuttle loom. When weaving is carried out with an air jet loom or the like, polyvinyl alcohol (PVA) or starch may be applied as a secondary size to achieve further lubricity.

The size pick-up, although not particularly limited, is preferably from 0.5 to 5 wt % with respect to the glass fibers (glass filament, yarn, cloth). At a size pick-up that is too low, fuzz and filament breakage may occur; when too much size adheres to the glass fibers, not only is there a loss of flexibility, removal of the size in a subsequent desizing step may be difficult.

The glass cloth prior to etching has a filament diameter of preferably 3.0 μm or more, and more preferably 3.5 μm or more. The filament diameter may exceed 10 μm, and may even be set to from 11 to 25 μm. When the filament diameter is too small or the glass cloth is too thin, handling during etching is difficult; when the filament diameter is too large or the glass cloth is too thick, the amount of glass cloth required for etching increases, which is undesirable in terms of productivity.

Etching of Glass Cloth

By etching the woven glass cloth having size thereon, the filament diameter of the glass cloth can be adjusted while suppressing fuzz formation, in addition to which removal of the size is also possible. The etching solution for adjusting the filament diameter is not particularly limited. Examples include one or more etching solution selected from among hydrofluoric acid, aqueous ammonium fluoride such as an aqueous solution of acidic ammonium fluoride (NH₄F·HF), aqueous sodium hydroxide, aqueous potassium hydroxide, aqueous sodium carbonate, ammonia water and alkaline electrolyzed water. Of these, in terms of the work environment and wastewater treatment, alkaline electrolyte water having a pH of 12.0 or more (as measured at 25° C.) is preferred.

The glass cloth etching conditions are not particularly limited, so long as the filament diameter can be adjusted. The temperature is preferably between room temperature (23° C.) and 100° C., and more preferably between 40 and 80° C. At a temperature below room temperature, etching may proceed too slowly; at an etching temperature above 100° C., the amount of etching may be difficult to regulate. The treatment time is adjusted according to the treatment temperature and the target filament diameter. For example, under treatment at 60° C., the diameter of quartz glass fibers can be reduced at a rate of about 0.035 μm per hour. Within a range of between 40 and 80° C. in particular, the treatment time is preferably from 3 to 100 hours, more preferably from 12 to 80 hours, and even more preferably from 25 to 72 hours.

After the target filament diameter has been reached, the glass cloth should be washed with pure or deionized water, preferably until the pH of the wash fluid becomes 7, following which moisture adhering to the glass cloth is removed by drying under applied heat. The method of washing includes, without particular limitation, such methods as dipping in wash water and spraying with wash water. In the case of dipping, stress such as ultrasound treatment may be applied. The drying method also is not particularly limited. Exemplary drying methods include hot-air drying, infrared drying and drying on heated rollers.

Deterioration in the strength of glass or glass cloth generally starts at surface microcracks. Microcracks in the surface of a glass cloth are chiefly caused by, for example, rubbing between filaments on the air jet loom during weaving or rubbing due to thermal expansion in heat cleaning. The etching treatment in this invention is able to remove size by etching treatment alone without resorting to heat cleaning treatment which causes microcracks. Hence, there is no need to carry out the heat cleaning at between 500° C. and 1,500° C. for desizing that is commonly used. In addition, surface microcracks that have formed during weaving of the glass cloth can be removed by etching, as a result of which the surface becomes uniform, enabling a high strength to be maintained.

Fiber-Opening of Glass Cloth

Fiber-opening treatment of the glass cloth is not particularly limited. Exemplary methods include fiber-opening treatment that utilizes ultrasound, treatment that employs a high-pressure, columnar water jet stream, and treatment which sprays a diffusion spray into the air. A method that utilizes a gas-liquid mixture mist having a calibrated air-water volume ratio is especially suitable in that the yarns in the fabric can be efficiently spread while suppressing strand slippage and fuzz formation. There is no particular limitation on the timing of fiber-opening treatment, although carrying it out before desizing is preferable in terms of taking advantage of the size lubricity. Also, because the size is removed during etching, the filaments more readily separate from one another, resulting in better fiber-opening. With such a fiber-opening method, the air permeability of a thin glass cloth can be set to 300 cm³/cm²/s or below. The air permeability is preferably from 30 to 280 cm³/cm²/s. The air permeability is measured in accordance with the method of measuring air permeability described in JIS R 3420.

Silane Treatment of Glass Cloth

The glass cloth that has been desized may be used directly as is or may be silane treated to give a silane-treated glass cloth. In the case of glass cloth that has been desized by prolonged etching, because the etching reaction is a glass decomposing reaction (Si—O—Si+OH—→SiOH+SiO—), SiOH groups readily form locally at the etched surface. By having the SiOH groups that have formed locally at the surface react with a silane coupling agent, the strength can be increased while lowering the dielectric loss tangent. The SiOH groups that form in heat cleaning take part in the chemical reaction at the surface (Si—O—Si+H₂O→2SiOH); owing to the high temperature, the radical reactions below proceed at once from the surface toward the interior.

H₂O→H.+.OH

Si—O—Si+H.→Si—OH+Si.

Si.+OH.→Si—OH

Hence, the method of removing size by etching is desirable also in that, because SiOH groups form not only at the surface but also at the interior, treatment with a silane coupling agent is impossible.

Examples of the silane coupling agent include, but are not limited to, alkoxysilane compounds such as trimethylmethoxysilane, trimethylethoxysilane, dimethyldimethoxysilane, dimethyldiethoxysilane, methylphenyldimethoxysilane, methylphenyldiethoxysilane, diphenyldimethoxysilane, diphenyldiethoxysilane, trimethoxysilane, triethoxysilane, methyltrimethoxysilane, methyltriethoxysilane, phenyltrimethoxysilane, phenyltriethoxysilane, phenylmethylvinylethoxysilane, naphthyltrimethoxysilane, naphthyltriethoxysilane, 1,4-bis(methoxydimethylsilyl)benzene, tetramethoxysilane, tetraethoxysilane, n-propyltriethoxysilane, hexyltrimethoxysilane, octyltriethoxysilane, decyltrimethoxysilane, 1,6-bis(trimethoxysilyl)hexane, vinyltrimethoxysilane, vinyltriethoxysilane, p-styryltrimethoxysilane, 3-aminopropyltrimethoxysilane, 3-glycidoxypropyltrimethoxysilane, 3-glycidoxypropylmethyldimethoxysilane, 3-glycidoxypropyltriethoxysilane, 3-glycidoxypropylmethyldiethoxysilane, 2-(3,4-epoxycyclohexyl)ethyltrimethoxysilane, 2-(3,4-epoxycyclohexyl)ethylmethyldimethoxysilane, 3-methacryloxypropyltrimethoxysilane, 3-methacryloxypropyldimethoxysilane, 3-methacryloxypropyltriethoxysilane, 3-methacryloxypropyldiethoxysilane, N-(2-aminoethyl)-3-aminopropyltrimethoxysilane, N-(2-aminoethyl)-3-aminopropylmethyldimethoxysilane, N-(2-aminoethyl)-3-aminopropyltriethoxysilane, N-(2-aminoethyl)-3-aminopropylmethyldiethoxysilane, N-phenyl-3-aminopropyltrimethoxysilane, N-(vinylbenzyl)-2-aminoethyl-3-aminopropyltrimethoxysilane and the hydrochloride thereof, N-(vinylbenzyl)-2-aminoethyl-3-aminopropylmethyldimethoxysilane and the hydrochloride thereof, 3-isocyanatopropyltriethoxysilane, tris(trimethoxy silylpropyl) isocyanurate, 3-ureidopropyltriethoxysilane, 3-chloropropyltrimethoxysilane, 3-mercaptopropyltrimethoxysilane, 3-mercaptopropylmethyldimethoxysilane and bis(triethoxysilylpropyl)tetrasulfide. One of these may be used alone or two or more may be used in admixture. Of these, 3-aminopropyltrimethoxysilane, N-(2-(aminoethyl)-3-aminopropyltrimethoxysilane and N-phenyl-3-aminiopropyltrimethoxysilane are preferred.

The silane treatment method is not particularly limited. Examples includes the method of dipping the glass fibers in an aqueous solution in which a silane coupling agent has been dispersed, and treatment by roll coating. A silane treatment method which, once the target filament diameter has been reached by etching treatment, adds a silane coupling agent to the etching solution is especially preferred as the method for silane treating thin glass cloth such as in this invention. The silane coupling agent is added in an amount which, although not particularly limited, should be such that the pick-up of silane coupling agent on the surface of the glass cloth following silane treatment is preferably from 0.01 to 1 wt %. For example, addition to a silane coupling agent concentration of from 0.01 to 1 wt % with respect to the etching solution is preferred. By having the pick-up of silane coupling agent on the glass cloth surface be 0.01 wt % or more, sufficient reaction with surface SiOH groups occurs, lowering the dielectric loss tangent. On the other hand, by having the pick-up of silane coupling agent on the glass cloth surface be 1 wt % or less, excess pick-up of the silane coupling agent on the surface of the glass cloth is avoided and the flexibility of the glass cloth is retained, in addition to which the dielectric loss tangent becomes lower. The treatment temperature is not particularly limited, although a temperature between 40° C. and 80° C. is preferred for the silane coupling agent to rapidly hydrolyze and react with the surface of the glass cloth. The treatment time is not particularly limited, provided that it is a treatment time such that the pick-up of silane coupling agent on the glass cloth surface following silane treatment is preferably from 0.1 to 1 wt %, although a treatment time of from 0.5 to 2 hours is preferred.

Following silane treatment, washing may be carried out with pure or deionized water until the pH of the washings becomes preferably 7. The moisture adhering to the glass cloth is then removed by drying under applied heat. At this time, excess silane coupling agent that is physically adsorbed and has not reacted with the glass cloth is removed.

Because the glass cloth obtained in the foregoing manner is not subjected to heat cleaning, the strength of the glass cloth can be maintained at a high level. Also, because the SiOH groups that have formed in the etching step are removed by silane treatment, the dielectric loss tangent can be made even lower.

Method of Adjusting Filament Diameter of Glass Cloth

This invention provides a method of adjusting the filament diameter of a glass cloth, which method includes the step of etching away at least 0.5 μm of the filament diameter by treating the glass cloth with one or more etching solution selected from the group consisting of hydrofluoric acid, aqueous ammonium fluoride, aqueous sodium hydroxide, aqueous potassium hydroxide, aqueous sodium carbonate, ammonia water and alkaline electrolyzed water. The etching method is the same as in the above-described glass cloth manufacturing method. The treatment temperature and treatment time are adjusted according to the target filament diameter. The filament diameter is cut in this way by preferably at least 0.5 μm, more preferably at least 1.0 μm, and even more preferably at least 2.0 μm. Although there is no upper limit, the reduction in the filament diameter may be suitably set to up to 10 μm. The etching solution used is preferably alkaline electrolyzed water having a pH of 12 or more. In particular, it is preferable for glass cloth having a filament diameter of 3.0 μm or more to be adjusted to a filament diameter of 0.5 μm or more and less than 3.0 μm by etching treatment with an etching solution. The filament diameter after etching is preferably 0.5 μm or more and less than 3.0 μm, more preferably from 0.5 to 2.9 μm, even more preferably from 1.0 to 2.5 μm, and still more preferably 1.0 μm or more and less than 2.5 μm.

Method of Desizing Glass Cloth

The invention provides a desizing method which includes the step of etching glass cloth which has a filament diameter of 3.0 μm or more and has size adhering to the surface so as to remove the size. The method of applying size and the etching method are the same as in the above-described glass cloth manufacturing method. The treatment temperature and treatment time are adjusted according to the target amount of size to be removed. Because desizing by etching essentially scrapes away the surfaces of the size-coated glass fibers, both water-soluble size and water-insoluble size can be removed. Removal of the size can be measured in accordance with the method of measuring loss on ignition described in JIS R 3420. At a loss on ignition of 0.1 wt % or less, the size can be confirmed to have been sufficiently removed. When silane coupling treatment has been carried out, the loss on ignition is preferably 0.3 wt % or less, and more preferably 0.25 wt % or less.

Prepreg for Printed Board

Because the glass cloth of the invention has a high strength and excellent dielectric properties, a printed board prepreg which is thinner and has a high strength and excellent dielectric properties can be obtained. The printed board prepreg is exemplified by prepregs containing the above glass cloth and an organic resin.

Laminate

Because the glass cloth of the invention has a high strength and excellent dielectric properties, a laminate which is thinner and has a high strength and excellent dielectric properties can be obtained. The laminate is exemplified by laminates containing the above glass cloth and an organic resin.

Printed Board

Because the glass cloth of the invention has a high strength and excellent dielectric properties, a printed board which is thinner and has a high strength and excellent dielectric properties can be obtained. The printed board is exemplified by printed boards containing the above glass cloth and an organic resin. The method of manufacturing the printed board is not particularly limited; a common printing board manufacturing method may be suitably used.

Examples of the organic resin include, without particular limitation, cyanate ester resins, bismaleimide-cyanate ester resins, epoxy resins, polyfunctional maleimide resins and unsaturated group-containing polyphenylene ether resins. One of these may be used alone or two or more may be used in combination. The amount of organic resin used falls within the known range for the art.

### EXAMPLES

The invention is illustrated more fully below by way of Examples and Comparative Examples, although the invention is not limited by these Examples.

Glass Cloth A

A primary size for quartz glass fibers composed of 3.0 wt % starch, 0.5 wt % beef tallow and 0.1 wt % emulsifying agent, with the balance being water, was prepared.

A glass ingot composed of 53 wt % SiO₂, 8 wt % B₂O₃, 15 wt % Al₂O₃, 21 wt % CaO, 2 wt % MgO and 1 wt % each of Na₂O and K₂O was hot drawn to produce glass fiber consisting of 4.0 μm diameter glass filaments and the above glass fiber size was applied thereto with an applicator, following which the filaments were collected together and taken up, producing glass strand having a glass filament count of 100. A twist of 24 T/m was applied to the wound-up glass strand to produce glass yarn.

An aqueous solution containing 1.5 wt % of polyvinyl alcohol (PVA) and 1.5 wt % of starch was applied as a secondary size to the resulting glass yarn, following which glass cloth was manufactured on an air jet loom at the weave density in IPC standard 1027. The resulting glass cloth with adhering size was subjected to fiber-opening treatment using a PSN slit nozzle from H. Ikeuchi Co., Ltd. and using 25° C., 0.3 MPa tap water and air compressed to 0.3 MPa at an air-water volume ratio V2/V1=35. The resulting glass cloth is denoted as “Glass Cloth A.” The amount of size adhering to Glass Cloth A was 1.8 wt %.

Glass Cloth B

Aside from setting the composition of the starting glass to 55 wt % SiO₂, 15 wt % B₂O₃, 15 wt % Al₂O₃, 12 wt % CaO, 2 wt % MgO and 1 wt % each of Na₂O and K₂O, a glass cloth was manufactured in the same way as Glass Cloth A at the weave density in IPC standard 1027, and fiber-opening treatment was carried out. The resulting glass cloth is denoted as “Glass Cloth B.” The amount of size adhering to Glass Cloth B was 1.6 wt %.

Glass Cloth C

Aside from using a quartz glass ingot that was 99.9 wt % SiO₂, a glass cloth was manufactured in the same way as Glass Cloth A at the weave density in IPC standard 1027, and fiber-opening treatment was carried out. The resulting glass cloth is denoted as “Glass Cloth C.” The amount of size adhering to Glass Cloth C was 1.5 wt %.

Glass Cloth D

Quartz glass filaments having a diameter of 3.6 μm were produced using a quartz glass ingot that was 99.9 wt % SiO₂, The resulting filaments were collected into 38-filament strands and weaving was carried out, thereby manufacturing a quartz glass cloth at the weave density in IPC standard 1006. Quartz glass yarn and cloth were subsequently produced in the same way as for Glass Cloth A, and fiber-opening treatment was carried out. The resulting glass cloth was denoted as “Glass Cloth D.” The amount of size adhering to Glass Cloth D was 2.0 wt %.

### Example 1

Glass Cloth A was placed in an alkali-resistant etching tank and S-2665 alkaline electrolyzed water (pH 12.0, as measured at 25° C.) from Suzukiyushi Industrial Co., Ltd. was poured in until the glass cloth was submerged. The tank was then airtightly closed and left at rest for 72 hours at 60° C., thereby carrying out etching. Next, 3-methacryloxypropyltrimethoxysilane (KBM-503, from Shin-Etsu Chemical Co., Ltd.) was added in an amount of 0.2 wt % with respect to the alkaline electrolyzed water and 1 hour of treatment was carried out at 60° C. The alkaline electrolyzed water was then discharged from the etching tank and replaced (three times) with deionized water until the pH reached 7, thereby rinsing the glass cloth. The rinsed and etched cloth was dried for 10 minutes at 110° C. using a DKN602 forced-air convection oven from Yamato Scientific Co., Ltd.

### Example 2

Glass Cloth B was placed in an alkali-resistant etching tank and coupling treatment was carried out simultaneous with etching treatment in the same way as in Example 1, after which the glass cloth was rinsed and then dried.

### Example 3

Glass Cloth C was placed in an alkali-resistant etching tank and coupling treatment was carried out simultaneous with etching treatment in the same way as in Example 1, after which the glass cloth was rinsed and then dried.

### Example 4

Glass Cloth C was placed in an alkali-resistant etching tank and, aside from changing the temperature during etching to 70° C. and changing the etching time to 54 hours, treatment was carried out in the same way as in Example 3.

### Example 5

Glass Cloth C was placed in an alkali-resistant etching tank and, aside from changing the etching time to 100 hours, treatment was carried out in the same way as in Example 3.

### Example 6

Glass Cloth C was placed in an alkali-resistant etching tank and, aside from changing the etching time to 31 hours, treatment was carried out in the same way as in Example 3.

### Example 7

Glass Cloth D was placed in an alkali-resistant etching tank and coupling treatment was carried out simultaneous with etching treatment in the same way as in Example 1, after which the glass cloth was rinsed and then dried.

### Comparative Example 1

A primary size for glass fibers composed of 3.0 wt % starch, 0.5 wt % beef tallow and 0.1 wt % Emulmin (Sanyo Chemical Industries, Ltd.) as an emulsifying agent, with the balance being water, was prepared. A glass ingot composed of 40 wt % SiO₂, 8 wt % B₂O₃, 22 wt % Al₂O₃, 27 wt % CaO, 2 wt % MgO and 1 wt % each of Na₂O and K₂O was hot drawn to produce glass fiber consisting of 4.0 μm diameter glass filaments and the above glass fiber size was applied thereto with an applicator, following which the filaments were collected together and taken up, producing glass strand having a glass filament count of 100. A twist of 24 T/m was applied to the wound-up glass strand to produce a glass yarn.

An aqueous solution containing 1.5 wt % of PVA and 1.5 wt % of starch was applied as a secondary size to the resulting glass yarn, following which glass cloth was manufactured on an air-jet loom at the weave density in IPC standard 1027.

The resulting glass cloth with adhering size was subjected to fiber-opening treatment using a PSN slit nozzle from H. Ikeuchi Co., Ltd. and using 25° C., 0.3 MPa tap water and air compressed to 0.3 MPa at an air-water volume ratio V2/V1=35.

The resulting glass cloth is denoted as “Glass Cloth E,” and was subjected to treatment in the same way as in Example 1.

### Comparative Example 2

Aside from changing the Glass Cloth C etching time to 110 hours, treatment was carried out in the same way as in Example 1.

### Comparative Example 3

Aside from changing the Glass Cloth C etching temperature to 10° C. and the etching time to 110 hours, treatment was carried out in the same way as in Example 1.

### Reference Examples

Glass Cloths A to C were subjected to 72 hours of heat cleaning treatment at 400° C. in a heating oven (gas-fired, 7 m³ Fiber Superio Kiln, from Mino Ceramic Co., Ltd.), giving a heat cleaning-treated glass cloth. An aqueous silane treatment solution containing 0.5 wt % of 3-methacryloxypropyltrimethoxysilane (KBM-503, from Shin-Etsu Chemical Co., Ltd.) was prepared and the resulting heat cleaning-treated glass cloth was immersed therein to a 3-methacryloxypropyltrimethoxysilane pickup of 0.2 wt % and then dried for 10 minutes at 110° C. in a DKN602 forced-air convection oven from Yamato Scientific Co., Ltd., thereby giving in each reference example a silane-treated glass cloth.

The glass cloths obtained above were evaluated by the following methods. The results are presented in Tables 1 and 2 below.

1. Measurement of Filament Diameter:

The glass cloth was vertically fixed using a cold-setting epoxy resin (NER-814, from Nisshin-EM) and the surface was polished, following which the glass filament diameter was measured in ten places with a scanning electron microscope (JSM-IT700HR InTouchScope™, JEOL, Ltd.) and the average of these values was treated as the filament diameter.

2. Measurement of Thickness:

The thickness was measured in accordance with the cloth and mat thickness measurement method described in JIS R 3420.

3. Measurement of Basis Weight:

The weight was measured in accordance with the cloth and mat weight measurement method described in JIS R 3420.

4. Measurement of Air Permeability:

The air permeability was measured in accordance with the method of measuring the air permeability of cloth described in JIS R 3420.

5. Measurement of Dielectric Loss Tangent:

The dielectric loss tangents of glass cloth at 10 GHz and 40 GHz was measured using a cavity resonator from AIT (TE011 mode). The thickness of the glass cloth was measured using the theoretical film thickness, the theoretical film thickness of glass cloth being computed as follows:

Theoretical film thickness t (μm)=weight (g/m²)/specific gravity (g/cm³)

6. Tensile Strength:

The tensile strength was measured in accordance with the method of measuring tensile strength described in JIS R 3420. The result is expressed as the following tensile strength (GPa).

Tensile strength (GPa)=(tensile strength (N/25 mm)×specific gravity (2.2 g/cm³))/(25×weight (g/m²))

7. Measurement of Loss on Ignition:

The loss on ignition (size residue) of the glass cloth before treatment with 3-methacryloxypropyltrimethoxysilane and the loss on ignition of the final glass cloth following treatment with 3-methacryloxypropyltrimethoxysilane were each measured in accordance with the method for measuring loss on ignition described in JIS R 3420.

TABLE 1

| | | Example | | | | | | |
|---|---|---|---|---|---|---|---|---|
| | | 1 | 2 | 3 | 4 | 5 | 6 | 7 |
| Glass cloth | Glass cloth | A | B | C | C | C | C | D |
| before | Amount of SiO₂ (wt %) | 53 | 55 | 99.9 | 99.9 | 99.9 | 99.9 | 99.9 |
| etching | Amount of SiO₂ + B₂O₃ (wt %) | 61 | 70 | 99.9 | 99.9 | 99.9 | 99.9 | 99.9 |
| | Glass cloth standard | 1027 | 1027 | 1027 | 1027 | 1027 | 1027 | 1006 |
| | Filament diameter (μm) | 4.0 | 4.0 | 4.0 | 4.0 | 4.0 | 4.0 | 3.6 |
| | Cloth thickness (μm) | 20.0 | 20.0 | 20.0 | 20.0 | 20.0 | 20.0 | 11.0 |
| | Weight (g/m²) | 20.0 | 17.7 | 16.5 | 16.5 | 16.5 | 16.5 | 7.5 |
| Etching | Temperature (° C.) | 60 | 60 | 60 | 70 | 60 | 60 | 60 |
| conditions | Time (h) | 72 | 72 | 72 | 54 | 100 | 31 | 60 |
| | Size residue (wt %) | 0.01 | 0.01 | 0.01 | 0.02 | 0.01 | 0.02 | 0.01 |
| Glass cloth | Filament diameter (μm) | 1.5 | 1.5 | 1.5 | 1.5 | 0.5 | 2.9 | 1.5 |
| after | Cloth thickness (μm) | 7.1 | 6.9 | 7.0 | 6.9 | 4.1 | 14.7 | 6.7 |
| etching | Weight (g/m²) | 2.8 | 2.5 | 2.3 | 2.3 | 0.3 | 8.7 | 1.3 |
| | Air permeability (cm³/cm²/s) | 144 | 137 | 146 | 150 | 282 | 72 | 178 |
| | Loss on ignition (wt %) | 0.2 | 0.2 | 0.2 | 0.2 | 0.5 | 0.2 | 0.2 |
| | Dielectric loss tangent (10 GHz) | 0.0063 | 0.0015 | 0.0006 | 0.0006 | 0.0006 | 0.0006 | 0.0006 |
| | Dielectric loss tangent (40 GHz) | 0.0082 | 0.0029 | 0.0009 | 0.0009 | 0.0009 | 0.0009 | 0.0009 |
| | Tensile strength (GPa) | 0.40 | 0.38 | 0.34 | 0.34 | 0.24 | 0.36 | 0.33 |

TABLE 2

| | | Comparative Example | | | Reference Example | | |
|---|---|---|---|---|---|---|---|
| | | 1 | 2 | 3 | 1 | 2 | 3 |
| Glass cloth | Glass cloth | E | C | C | A | B | C |
| before | Amount of SiO₂ (wt %) | 40 | 99.9 | 99.9 | 53 | 55 | 99.9 |
| etching | Amount of SiO₂ + B₂O₃ (wt %) | 48 | 99.9 | 99.9 | 61 | 70 | 99.9 |
| | Glass cloth standard | 1027 | 1027 | 1027 | 1027 | 1027 | 1027 |
| | Filament diameter (μm) | 4.0 | 4.0 | 4.0 | 4.0 | 4.0 | 4.0 |
| | Cloth thickness (μm) | 20.0 | 20.0 | 20.0 | 20.0 | 20.0 | 20.0 |
| | Weight (g/m²) | 20.5 | 16.5 | 16.5 | 20.0 | 17.7 | 16.5 |
| Etching | Temperature (° C.) | 60 | 60 | 10 | — | — | — |
| conditions | Time (h) | 72 | 110 | 110 | — | — | — |
| | Size residue (wt %) | 0.01 | 0.01 | 0.82 | — | — | — |
| Glass cloth | Filament diameter (μm) | 1.5 | 0.3 | 4.0 | — | — | — |
| after | Cloth thickness (μm) | 6.8 | 3.7 | 20.0 | — | — | — |
| etching | Weight (g/m²) | 2.9 | 0.1 | 16.5 | — | — | — |
| | Air permeability (cm³/cm²/s) | 145 | 340 | 380 | — | — | — |
| | Loss on ignition (wt %) | 0.2 | 0.5 | 0.2 | 0.2 | 0.2 | 0.2 |
| | Dielectric loss tangent (10 GHz) | 0.0070 | 0.0006 | 0.0006 | 0.0067 | 0.0019 | 0.0016 |
| | Dielectric loss tangent (40 GHz) | 0.0089 | 0.0010 | 0.0009 | 0.0085 | 0.0035 | 0.0025 |
| | Tensile strength (GPa) | 0.03 | 0.04 | 0.33 | 0.23 | 0.17 | 0.15 |

The results in Table 1 show that glass cloth having a filament diameter of 0.5 μm or more and less than 3.0 μm, a thickness of 15 μm and a weight of from 0.3 to 10 g/m² can be obtained by the method of the invention. In addition, because the manufacturing method of the invention is a method which desizes without carrying out heat cleaning, compared with the Reference Examples having the same glass formulations, the tensile strength can be increased while keeping the dielectric loss tangent low. At a higher total content of SiO₂ and B₂O₃, the dielectric properties become lower than in the Reference Examples, but the strength decreases. The decrease in strength due to heat cleaning is especially pronounced in glass cloth having a SiO₂ content of 99.9 wt % or more, and so this invention is particularly useful in quartz glass cloth having a SiO₂ content of 99.9 wt % or more. In Comparative Example 1, the filament diameter can be similarly adjusted by etching, but because ingredients other than SiO₂ are etched more quickly than SiO₂, etching proceeds rapidly and cracks form in those areas, as a result of which the strength cannot be maintained. In Comparative Example 2, the single fiber diameter can be reduced below 0.5 μm by increasing the etching time, but this is undesirable because the strength becomes extremely low. In Comparative Example 3, although size on the surface of the glass cloth can be removed at 10° C., the energy needed for the etching to proceed is insufficient, and so the filament diameter cannot be adjusted as desired.

In this invention, by adjusting the filament diameter at a later stage of production via etching treatment, not only is it possible to obtain thin glass cloth having a filament diameter of less than 3 μm and a thickness of 15 μm or less, which has to date been impossible to weave, desizing can be carried out at the same time, enabling thin glass cloth having a low dielectric loss tangent and a high strength to be achieved. The thin glass cloth obtained in this way enables printed wiring board integration applicable to high-speed communications technologies such as 5G which will see increasing use in the future and also helps to hold down transmission loss.

Japanese Patent Application No. 2022-174385 is incorporated herein by reference. Although some preferred embodiments have been described, many modifications and variations may be made thereto in light of the above teachings. It is therefore to be understood that the invention may be practiced otherwise than as specifically described without departing from the scope of the appended claims.

1. A glass cloth comprising glass having a composition that is at least 50 wt % SiO₂, wherein the glass cloth has a filament diameter of 0.5 μm or more and less than 3.0 μm, a thickness of 15 μm or less and a weight of from 0.3 to 10 g/m².

2. The glass cloth of claim 1, wherein the composition includes a combined amount of SiO₂ and B₂O₃ that is 65 wt % or more.

3. The glass cloth of claim 1, wherein the composition is at least 95 wt % SiO₂.

4. A method of manufacturing glass cloth of claim 1, comprising the step of etching the glass cloth with one or more etching solution selected from the group consisting of hydrofluoric acid, aqueous ammonium fluoride, aqueous sodium hydroxide, aqueous potassium hydroxide, aqueous sodium carbonate, ammonia water and alkaline electrolyzed water.

5. A method of adjusting the filament diameter of a glass cloth, comprising the step of etching away at least 0.5 μm of the filament diameter by treating the glass cloth with one or more etching solution selected from the group consisting of hydrofluoric acid, aqueous ammonium fluoride, aqueous sodium hydroxide, aqueous potassium hydroxide, aqueous sodium carbonate, ammonia water and alkaline electrolyzed water.

6. The filament diameter adjusting method of claim 5, wherein the etching solution is alkaline electrolyzed water having a pH of 12 or more.

7. The filament diameter adjusting method of claim 5, wherein glass cloth having a filament diameter of 3.0 μm or more is etched with an etching solution to adjust the filament diameter to 0.5 μm or more and less than 3.0 μm.

8. A desizing method comprising the step of etching glass cloth which has a filament diameter of 3.0 μm or more and in which size adheres to filament surfaces so as to remove the size.

9. A prepreg comprising the glass cloth of claim 1 and an organic resin.

10. A laminate comprising the glass cloth of claim 1 and an organic resin.

11. A printed wiring board comprising the glass cloth of claim 1 and an organic resin.
